(19) United States
(12) Patent Application Publication
(10) Pub. No.: US 2006/0181320 A1
(43) Pub. Date: Aug. 17, 2006

(54) Circuit for optimizing the duty cycle of a received clock transmitted over a transmission line

(75) Inventors: Daniel M. Dreps, Georgetown, TX (US); Frank D. Ferraiolo, New Windsor, NY (US); Robert J. Reese, Austin, TX (US); Glen A. Wiedemeier, Austin, TX (US)

Correspondence Address: IBM CORP (WSM);C/O WINSTEAD SECHREST & MINICK P.C., PO BOX 50784, DALLAS, TX, 75201, US

(73) Assignee: International Business Machines Corporation, Armonk, NY (US)

(21) Appl. No.: 11/055,851

(22) Filed: Feb. 11, 2005

(51) Int. Cl. H03L 7/06

(52) U.S. Cl. 327/175

(57) ABSTRACT

Data signals are transmitted over transmission lines in groups to receivers in a receiving IC. Each group of data signals has a differential clock used in synchronizing and detecting the data signals. The data signal eye windows vary with timing jitter in the data signals relative to the clock edges and the asymmetry in a compensated clock signal detected from the differential clock using a duty cycle adjustment circuit. Error detection determines if the clock asymmetry is affecting the eye window of the data signals. Control signals selectively adjust the gain of differential stages generating the compensated clock to modify the duty cycle of the compensated clock. The eye window of the data signals are monitored and used as feedback to servo the control signals to optimize the duty cycle of the compensated clock signal for sampling the data signals.

### TECHNICAL FIELD

The present invention relates in general to board level transmission line drivers and receivers, and in particular, to receiver circuits for shaping receiver transmission line signals for optimum signal detection.

### BACKGROUND INFORMATION

Digital computer systems have a history of continually increasing the speed of the processors used in the system. As computer systems have migrated towards multiprocessor systems, sharing information between processors and memory systems has also generated a requirement for increased speed for the off-chip communication networks. Designers usually have more control over on-chip communication paths than for off-chip communication paths. Off-chip communication paths are longer, have higher noise, impedance mismatches, and have more discontinuities than on-chip communication paths. Since off-chip communication paths are of lower impedance, they require more current and thus more power to drive.

When using inter-chip high-speed signaling, noise and coupling between signal lines (crosstalk) affects signal quality. One way to alleviate the detrimental effects of noise and coupling is through the use of differential signaling. Differential signaling comprises sending a signal and its complement to a differential receiver. In this manner, noise and coupling affect both the signal and the complement equally. The differential receiver only senses the difference between the signal and its complement as the noise and coupling represent common mode signals. Therefore, differential signaling is resistant to the effects that noise and crosstalk have on signal quality. On the negative side, differential signaling increases pin count by a factor of two for each data line. The next best thing to differential signaling is pseudo-differential signaling. Pseudo-differential signaling comprises comparing a data signal to a reference voltage using a differential receiver or comparator.

When high speed data is transmitted between chips, the signal lines are characterized by their transmission line parameters. High speed signals are subject to reflections if the transmission lines are not terminated in an impedance that matches the transmission line characteristic impedance. Reflections may propagate back and forth between driver and receiver and reduce the margins when detecting signals at the receiver. Some form of termination is therefore usually required for all high-speed signals to control overshoot, undershoot, and increase signal quality. Typically, a Thevenin's resistance (equivalent resistance of the Thevenin's network equals characteristic impedance of transmission line) is used to terminate data lines allowing the use of higher valued resistors. Additionally, the Thevenin's network is used to establish a bias voltage between the power supply rails. In this configuration, the data signals will then swing around this Thevenin's equivalent bias voltage. When this method is used to terminate data signal lines, a reference voltage is necessary to bias a differential receiver that operates as a pseudo-differential receiver to detect data signals in the presence of noise and crosstalk.

The logic levels of driver side signals are determined by the positive and ground voltage potentials of the driver power supply. If the driver power supply has voltage variations that are unregulated, then the logic one and logic zero levels of the driver side signals will undergo similar variations. If the receiver is substantially remote from the driver such that its power supply voltage may undergo different variations from the driver side power supply, then additional variations will be added to any signal received in a receiver side terminator (e.g., Thevenin's network). These power supply variations will reduce noise margins if the reference has variations different from those on the received signals caused by the driver and receiver side power supply variations.

The popular technique of source-synchronous clocking is often used for high speed interface systems. With this technique, the transmitting device sends a clock with the data. The advantage of this approach is that the maximum performance is no longer computed form the clock-to-output delay, propagation delay, and set up times of the devices and the circuit board. Instead, the maximum performance is related to the maximum edge rate of the driver and the skew between the data signals and the clock signals. Using this technique, data may be transferred at a 1 Gbps rate (1-nsec bit period) even though the propagation delay from transmitter to receiver may exceed one nanosecond. If standard double-data rate (DDR) driving is utilized, data is launched on both the rising and falling edges of the clock. In this case, duty cycle symmetry of the clock as detected at the receiver becomes important since each edge of the clock is also used to recover the data at the receiving end of the data path. If the clock is asymmetrical, then it will affect the eye pattern of the data signals that the clock is used to detect.

There is, therefore, a need for circuitry to measure the effect of the clock duty cycle asymmetry on data signals in the receiver side and apply correction to minimize the duty cycle distortion in receiver side detected clocks.

### SUMMARY OF THE INVENTION

Clock signals sent with each group of data signals are detected at the receiver side. A circuit determines a maximum data eye window size for the data bits within the group recovered with the clock. Functional delay is added to the data path so a clock edge sampling the data is centered in the data eye window. The clock edge is centered in the data eye window when Setup guardband delay added to the functional delay and Hold guardband delay added to the clock are determined to be equally spaced around the sample point. Setup guardband and Hold guardband failures occur when the data with the functional delay and the Setup guardband delay, sampled with the clock, and the data with the functional delay sampled with the clock delayed by the Hold guardband delay, do not all register the same logic state when sampled over multiple clock periods. Excess edge failure indications occur when the group data signals register excessive rates of Setup guardband or Hold guardband failures which signify that the asymmetry in the duty of the clock may be adversely affecting the group data eye patterns. The Setup and Hold guardband delays are set to the maximum value that eliminates Setup and Hold guardband failures for a given Functional delay. A maximized eye pattern window is determined by setting the Functional delay to a minimum and the Hold and Setup delays to their maximums. The Functional delay is then varied across its range and Hold and Setup errors are determined. This process is iterated until a Functional delay is found with maximum values of Hold and Setup delays that do not generate Hold and Setup errors.

The clock is detected in receiver circuitry that adjusts the duty cycle of the clock in response to duty cycle control signals. Logic control circuitry receives the Hold and Setup error signals and generates the program values for the Functional, Hold and Setup delays and iterates the delay values to determine a Functional delay with maximum guardband delay values for a given setting of the duty cycle control signals (particular symmetry of the received clock). The eye window maximizer circuit determines a maximum eye window size and holds a present value. The duty cycle control signals adjust the duty cycle of the clock signal and the data path delays are again cycled to determine a present maximum value for the Setup and Hold guardbands. If the present maximum value is greater than the held present value, then it is substituted for the present value after each iteration. The duty cycle setting that achieves the maximum eye window size after trying all compensation stimulus values is set as the operational value to optimize the clock's duty cycle.

The foregoing has outlined rather broadly the features and technical advantages of the present invention in order that the detailed description of the invention that follows may be better understood. Additional features and advantages of the invention will be described hereinafter which form the subject of the claims of the invention.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 is a block diagram of a clock group according to embodiments of the present invention;

FIG. 2 is a circuit diagram of data and clock transmission paths suitable for practicing embodiments of the present invention;

FIG. 3 is an exemplary eye pattern of a logic data signal transmitted over a transmission line;

FIG. 4 is a block diagram of eye pattern maximizer circuitry and a clock duty cycle compensation circuitry according to embodiments of the present invention;

FIG. 5 is a detailed block diagram of data eye pattern maximizer circuitry with clock duty cycle compensation circuitry;

FIG. 6 is a circuit diagram of the clock duty cycle compensation circuitry according to embodiments of the present invention;

FIG. 7A is a detailed circuit diagram of one of the programmable gain stages in the clock duty cycle compensation circuitry according to embodiments of the present invention;

FIG. 7B is a detailed circuit diagram of the output differential stage in the clock duty cycle compensation circuitry according to embodiments of the present invention;

FIG. 8 is a flow diagram of method steps used in embodiments of the present invention; and

FIG. 9 is a data processing system suitable for practicing embodiments of the present system.

### DETAILED DESCRIPTION

In the following description, numerous specific details are set forth to provide a thorough understanding of the present invention. However, it will be obvious to those skilled in the art that the present invention may be practiced without such specific details. In other instances, well-known circuits may be shown in block diagram form in order not to obscure the present invention in unnecessary detail. For the most part, details concerning timing considerations and the like have been omitted inasmuch as such details are not necessary to obtain a complete understanding of the present invention and are within the skills of persons of ordinary skill in the relevant art.

Refer now to the drawings wherein depicted elements are not necessarily shown to scale and wherein like or similar elements are designated by the same reference numeral through the several views.

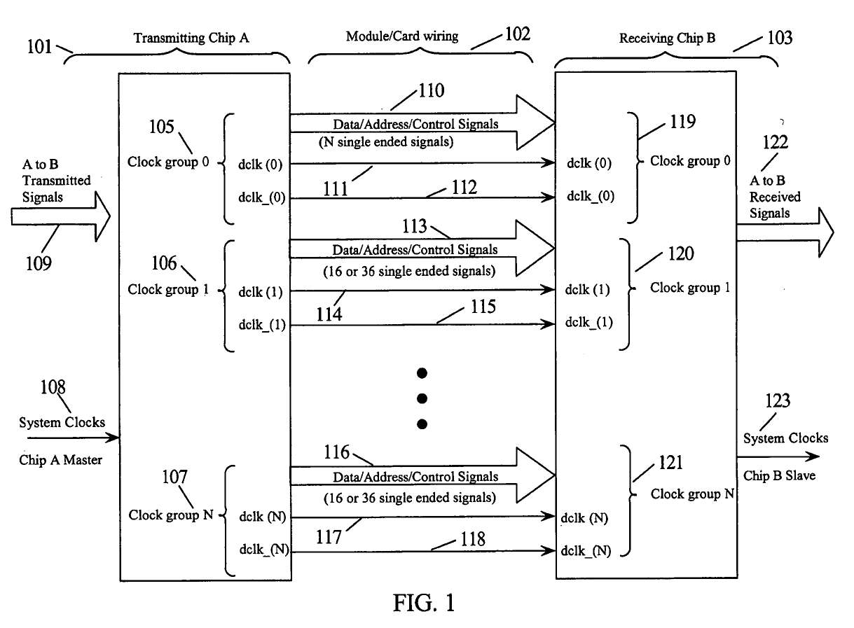

FIG. 1 is a block diagram of clock groups communicating between two chips where the signals may use pseudo-differential signaling. A transmitting integrated circuit (IC) chip A 101 receives signals 109 and system clocks 108 and transmits them over module/card wiring 102 to receiving IC chip B 103. Signals 109 are partitioned into “clock groups” in that a separate clock signal pair (clock signal and its complement) is sent with each signal group. Clock group 0 comprises Data/Address/Control Signals 110 and clock Dclk (0) 111 and Dclk_(0) 112. Clock group 1 comprises Data/Address/Control Signals 113 and clock Dclk (1) 114 and Dclk_(1) 115 and Clock group N comprises Data/Address/Control Signals 116 and clock Dclk (N) 117 and Dclk_(N) 118. The signals and clocks in these groups are received in receivers (not shown) as Clock group 0 119-Clock group (N) 121 and are detected to generate received signals 122 and system clocks 123.

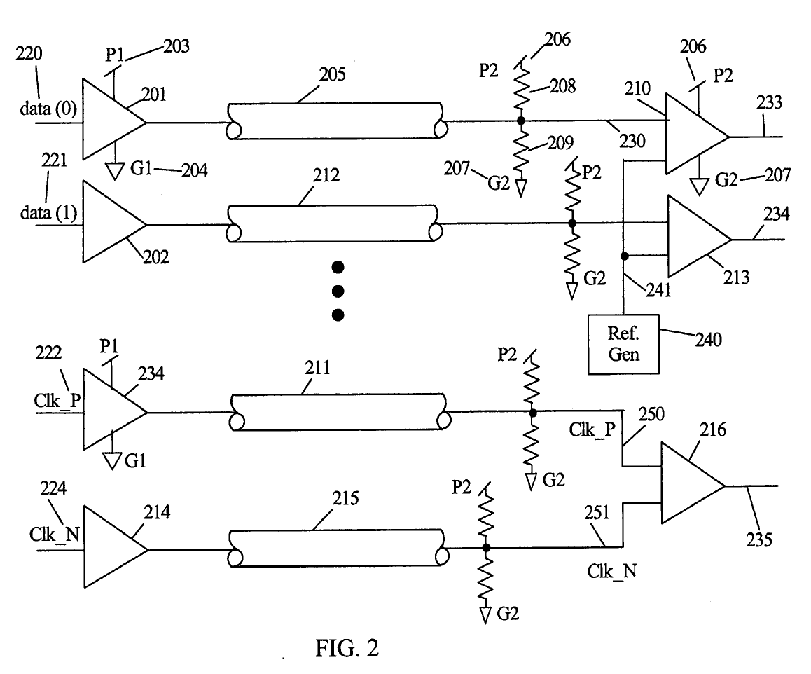

FIG. 2 is a circuit diagram of typical pseudo-differential signaling suitable for practicing embodiments of the present invention where data is transmitted from a driver to a receiver (e.g., within a clock group (0) 105 in FIG. 1). Exemplary reference generator (RG) 240 is used to generate a single reference (e.g., Vref 241) for multiple receivers (e.g., 210 and 213) within a clock group (e.g., within a clock group (0) 105 in FIG. 1). Drivers 201 and 202 represent two of a number of N drivers sending data to receivers 210 and 213, respectively. Exemplary driver 201 receives data 0 220 and generates an output that swings between power supply rail voltages P1 203 (logic one) and G1 204 (logic zero). When the output of driver 201 is at P1 203, any noise on the power bus is coupled to transmission line 205 along with the logic state of the data signal. Exemplary transmission line 205 is terminated with a voltage divider comprising resistors 208 and 209. Exemplary receiver input 230 has a DC bias value determined by the voltage division ratio of resistors 208 and 209 and the voltage between P2 206 and G2 207. Exemplary receiver 210 is powered by voltages P2 206 and G2 207 which may have different values from P1 203 and G1 204 due to distribution losses, noise coupling, and dynamic impedance of the distribution network. Exemplary receiver 210 is typically a voltage comparator or high gain amplifying means that amplifies the difference between a signal at input 230 and a reference voltage 241. In this circuitry, driver side noise will not be reduced by common mode rejection as the reference voltage (e.g., Vref 241) does not contain driver side noise but rather reflects noise of the receiver side. A clock signal Clk_P 222 and its complement Clk_N 224 are coupled to transmission lines (TL) 211 and TL 215 with drivers 234 and 214, respectively. The clock signals Clk_P 222 and Clk_N 224 are received as Clk_P 250 and Clk_N 251 in a differential receiver 216 that may employ duty cycle compensation circuitry according to embodiments of the present invention. Differential receiver circuitry 216 generates a single ended signal at output 235 which may then be buffered for distribution within an IC.

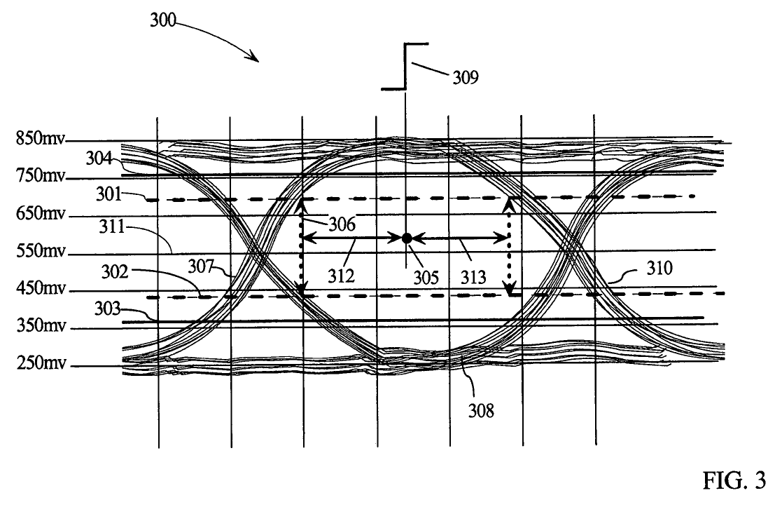

Various signal characteristics may be monitored in determining what metric to use in setting an optimum value of variables affecting an eye pattern 300. FIG. 3 illustrates a superposition of many received signals (e.g., at node 233) from a transmission line (TL) (e.g., TL 205). FIG. 3 defines what is meant by the “eye window” of a waveform as discussed in embodiments of the present invention. If one alternates between sending a repetitive signal and its complement, then a time lapse oscillograph of received waveforms would show that the waveform transitions between a logic one and a logic zero actually vary (e.g., positive transitions 307 and negative transitions 310). The actual voltage levels corresponding to a logic one (309) and a logic zero (308) also show dynamic variances. The voltage value of the “eye window” is illustrated by arrow 306 between voltage levels 301 and 302 and the time value is illustrated by arrows 312 and 313 between the transitions above voltage levels 301 and 302. Voltage level 301 illustrates the voltage above where a received signal is defined as a logic one and level 302 illustrates the voltage below where a received signal is defined as a logic zero. The crossover point 311 (voltage 550 mv) may be an ideal threshold voltage for a receiver detecting waveforms 300. The voltage between 301 and 311 may be called the positive signal-to-noise margin and the voltage between 311 and 302 may be called the negative signal-to-noise margin. Noise margins may be one way to determine an optimum value to use to set a reference voltage (e.g., Vref 241) for detecting a pseudo-differential signal generated at a receiver output (e.g., 233).

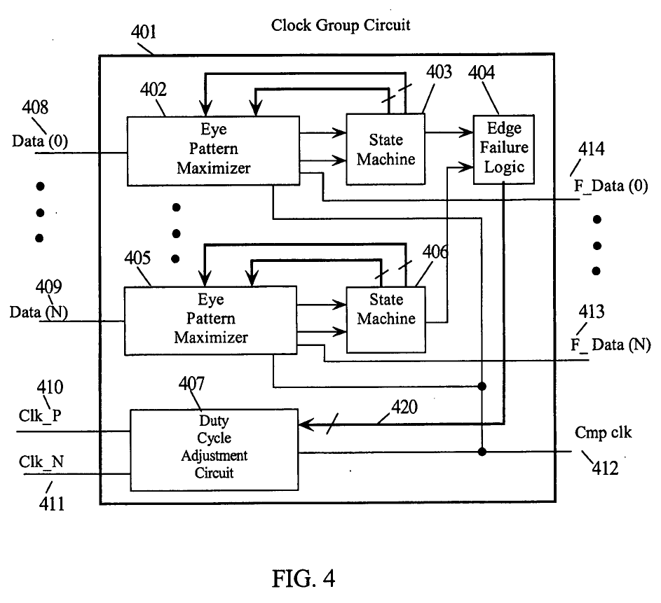

If the data 300 was sampled by a clock transition 309, it would be ideal to have the clock transition occur at time 305 where the guardband times 312 and 313 from the ideal point to the data transitions are equal and maximum. If the clock 309 sample point 305 moved to the left more than guardband 312, then errors may occur. Likewise, if the clock sample point 305 moved right more than guardband 313, then errors may occur. Using this criteria it can be said that positioning data 300 relative to clock 309 as shown would have maximized the eye pattern window for detecting the logic states of data 300. If the clock generating clock edge 309 was asymmetrical or had timing jitter, then the effective eye window size would be diminished by the clock asymmetry and the jitter FIG. 4 is a block diagram of a group circuit 400 illustrating that each data signal in the group circuit 401 has eye pattern maximizer (EPM) circuitry and a clock duty cycle adjustment (DCA) circuit according to embodiments of the present invention. Each data signal (e.g., Data (0) 408) has its own eye pattern maximizer (EPM) circuitry (e.g., 402). A state machine (e.g., 403 for exemplary Data (0) 408) receives signals from EPM 402 and compensated clock (Cmp_Clk 412) and generates program values for delay lines (not shown) in EPM 402 used to shift the detected data signals relative to the clock to ensure the data signals are optimally aligned to their received clock. The state machine (e.g., 403) determines particular types of failures related to timing that causes it to generate program values for the delay lines in EPM 402. If it is determined that group circuit 401 has an excessive amount of failures attributed to the clock edges, (edge failures 404) then program values 420 for delay in DCA circuitry 407 are modified to adjust the symmetry of the Cmp_Clk 412 signal. State machines (e.g., 403 and 406) cycle through possible delay values and analyze the failures to determine a maximum eye pattern window. If excessive edge failures are again determined, then the adjustment process is again iterated until optimum delay values are determined for the EPM 402-405 circuits and for the DCA 407 circuitry. The functional data signals F_Data (0) 414 through F_Data (N) 413 and clock signal Cmp_Clk 412 are distributed to circuitry within the IC chip (e.g., receiving chip 103 in FIG. 1).

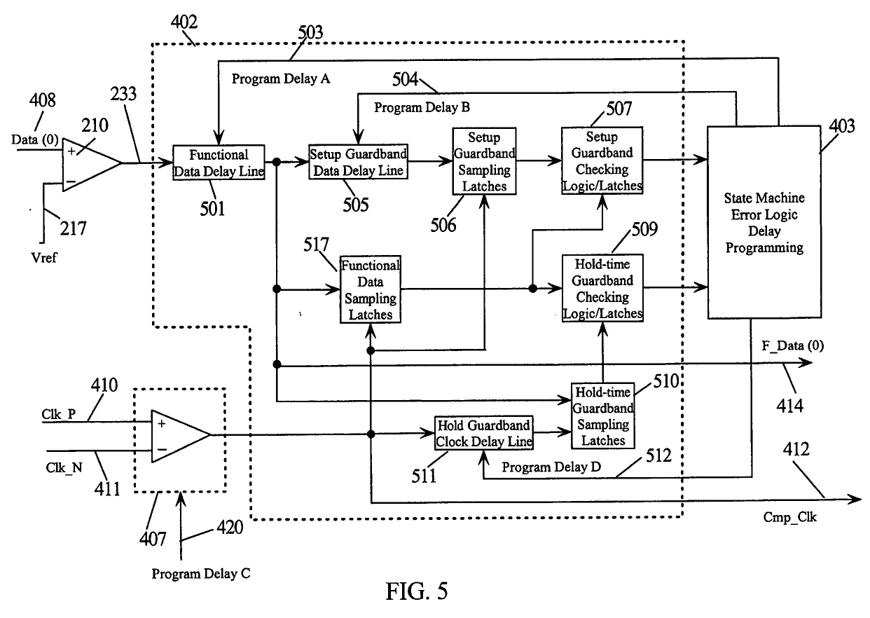

FIG. 5 is a detailed block diagram of circuits used within the data eye pattern maximizer and the clock duty cycle adjustment circuit according to embodiments of the present invention. An exemplary data signal Data (0) 408 (FIG. 4) is received in receiver 210 and detected with reference voltage Vref 217 (e.g., from FIG. 2). A detected data signal at output 233 is coupled to Functional Data Delay Line (FDDL) 501. FDDL 501 generates functional data signal F_Data (0) 414 by delaying Data (0) 408 relative to the Cmp_Clk 412 to de-skew the data signal. The circuitry in Data Delay Line 505 and circuit blocks 506, 507, 509, and 517 receive the F_Data (0) 414 and determine the timing relation between F_Data (0) 414 and Cmp_Clk 412. State machine 403 receives signals from blocks 507, 509 and programs the delays in FDDL 501 and DDL 505 to iteratively arrive at a maximum eye window size. Edge failures (e.g., 404 from FIG. 4) analyzed across a clock group (e.g., 401) determine whether to adjust the duty cycle of Cmp_Clk 412. If the program delay C 420 is adjusted, then the delay values (Program Delay A 503 and Program Delay B 504) are cycled to again determine the maximum eye pattern window for the data signals (e.g., Data (0) 408) in clock group 401.

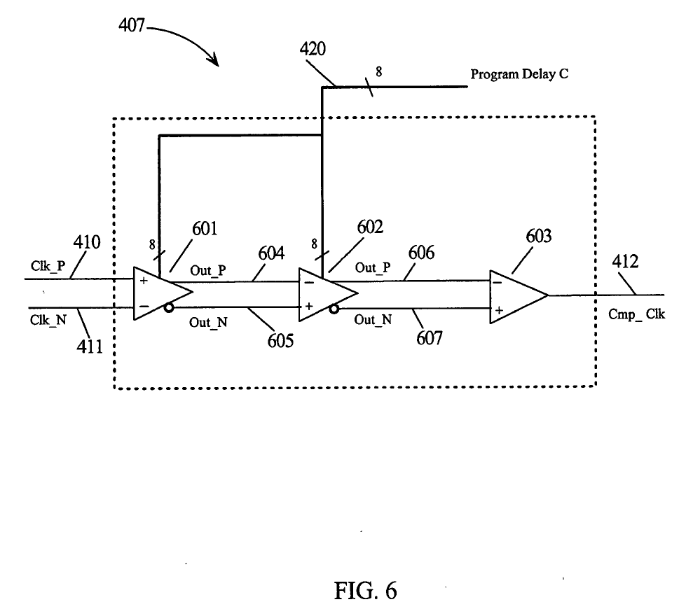

FIG. 6 is a circuit diagram of the exemplary DCA circuit 407 in FIG. 4 according to embodiments of the present invention. The complementary clock signals Clk_P 410 and Clk_N 411 are coupled to programmable differential stage (PDS) 601. PDS 601 receives Program Delay C 420 signals which are used to separately control the gain of the positive output 604 and the negative output 605 relative to the inputs Clk_P 410 and Clk_N 411. Positive output 604 generates a positive going signal when the difference (Clk_P 410 minus Clk_N 411) is positive going. In this case, Out_N 605 would be negative going. The PDS 602 receives the outputs of PDS 601 and likewise generates complementary outputs 606 and 607, wherein the gain of the two outputs relative to the differential inputs 604 and 605 is set by the Program Delay C 420 signals. Finally, differential amplifier 603 amplifies the differential signals 606 and 607 and produces a single ended output Cmp_Clk 412. By applying one programmed gain to the positive output and a separate programmed gain to the negative output of the first two differential stages and finally shaping the result in a last differential stage, the duty cycle of the clock signal may be modified. Doing this adjustment while using the eye pattern window of the data signals as the feedback, leads to a clock duty cycle that maximizes the eye pattern window of the data signals in a clock group (e.g., clock group 402). It is important to note that the stages are wired such that a positive going difference (e.g., positive transition) between Clk_P 410 minus Clk_N 411 will generate a positive transition at Out_P 410, a negative transition at Out_P 606 and a positive transition on Cmp_Clk 412. This assures that the signal transition on the input that generates a certain transition has the same programmed gain applied from input to output. While FIG. 6 shows particular circuit elements interpreted as classical differential amplifiers, other device configurations that provide the functionality of amplifying the difference between two inputs and producing a output with a first programmable gain and another complementary output with a second programmable gain are considered within the scope of the present invention.

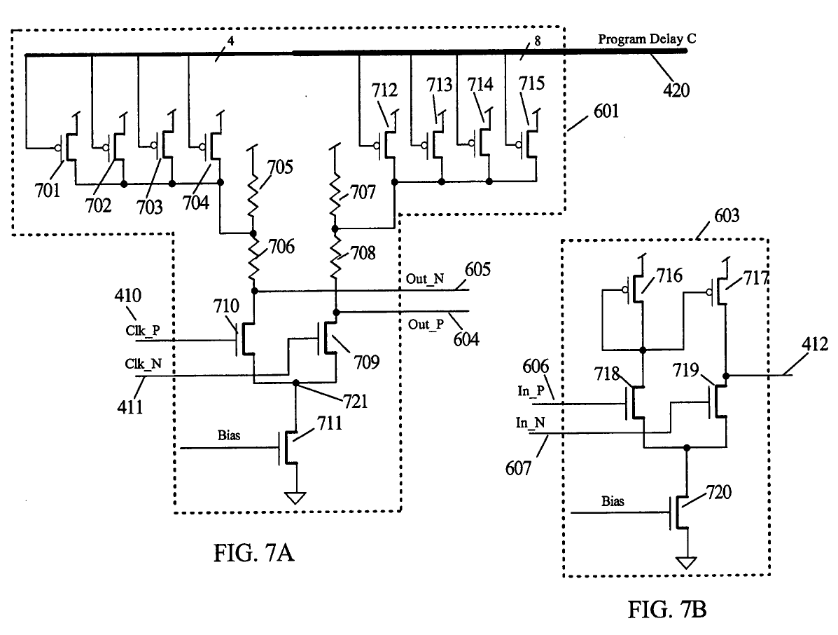

FIG. 7A is a detailed circuit diagram of a PDS 601 used in DCA 407 shown in FIG. 6 according to embodiments of the present invention. PDS 601 receives Program Delay C 420 signals which separately set the gain of the positive output Out_P 604 and the negative output Out_N 605. The exemplary Program Delay C 420 signals comprise 8 binary bits in this example but the invention is not limited to 8 binary bits. Four of the binary bits are used to program the gain of the circuitry generating Out_P 604 and 4 bits are used to program the gain of the circuitry generating Out_N 605. N channel field effect transistors (NFETS) 710 and 709 form a common source circuit biased by a current source NFET 711. The current in NFET 711 is set by the Bias 720 applied to its gate. The difference between the voltages Clk_P 410 and node 721 and Clk_N 411 and node 721 determine how much current flows through series load resistors 705 and 706 and series load resistors 707 and 708, respectively. PFETS 701-704 and 712-715 parallel resistors 705 and 707, respectively. If none of PFETS 701-704 are turned ON by Program Delay C 420 signals, then the voltage gain of Out_N 605 is the highest. As combinations of PFETS 701-704 are turned ON, the gain is reduced. Likewise, if none of PFETS 712-715 are turned ON by Program Delay C 420 signals, then the voltage gain of Out_P 604 is the highest. Again, turning ON combinations of PFETS 701-704 reduces the gain. In this manner, the differential signal between Clk_P 410 and Clk_N 411 has programmable and potentially different gains to Out_P 604 and Out_N 605.

FIG. 7B is a circuit schematic of a differential amplifier stage 603 used to shape the signals at In_P 606 and In_N 607 to generate Cmp_Clk 412. N channel field effect transistors (NFETS) 718 and 719 form a common source circuit biased by a current source NFET 720. The current in NFET 720 is set by the Bias 721 applied to its gate. The difference between the voltages at In_P 606 and node 722 and In_N 607 and node 722 determine how much current flows through series active load device PFET 717 and diode coupled PFET 716, respectively. The configuration of PFET 716 and 717 generates a high gain for the difference signal between In_P 606 and In_N 607 generating Cmp_Clk 412.

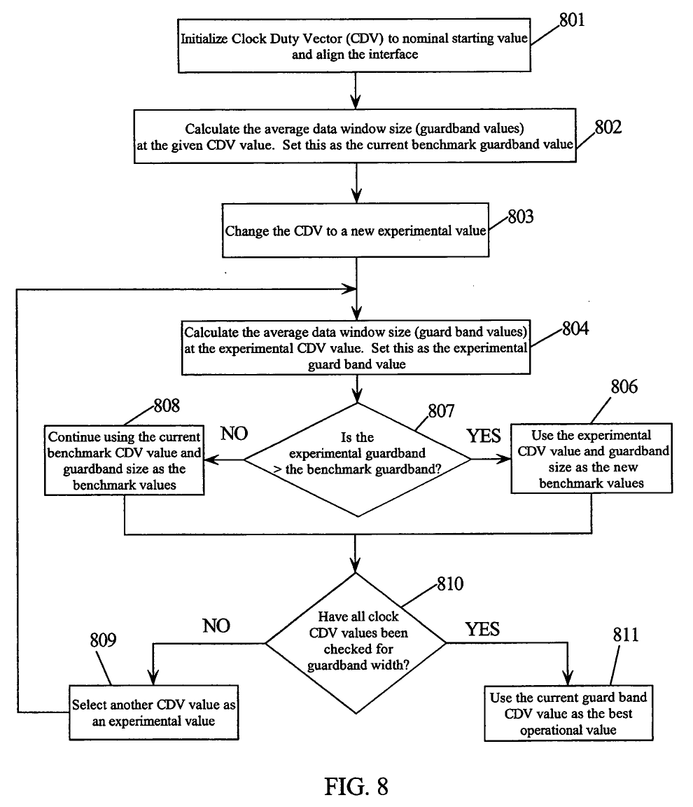

FIG. 8 is a flow diagram of method steps used in embodiments of the present invention. In step 801, the clock duty cycle for a clock group 401 is set to a nominal value and the interface is aligned. Aligning the interface comprises adjusting the delay for the functional delay lines (e.g., FDL 501) in each data path of clock group 410 and determining and storing a maximum eye window value. In step 802, the average eye window size is calculated and set to the current benchmark guardband value. In step 803, the Program Delay C 420 are adjusted to set a new value. The interface is again aligned and a new average experimental eye window guardband value is calculated. In step 807, a determination is made if the new experimental eye window guardband value is greater than the stored current benchmark guardband value. If the result of the test in step 807 is YES, then in step 806, the experimental guardband value is stored as the benchmark guardband value. In step 810, a test is done to determine if all the possible values of adjustment in the DCA 407 circuitry have been tried. If the result of the test in step 810 is YES, then in step 811, the value of the clock duty cycle is selected as the operational value for clock group 401. If the result of the test in step 810 is NO, then in step 809 a new value is selected and a branch is taken back to step 804 where a new average experimental guardband value is determined. If the result of the test in step 807 is NO, then in step 808 the current clock duty cycle value is kept as the benchmark value and steps 809, 810, and 811 are executed as above.

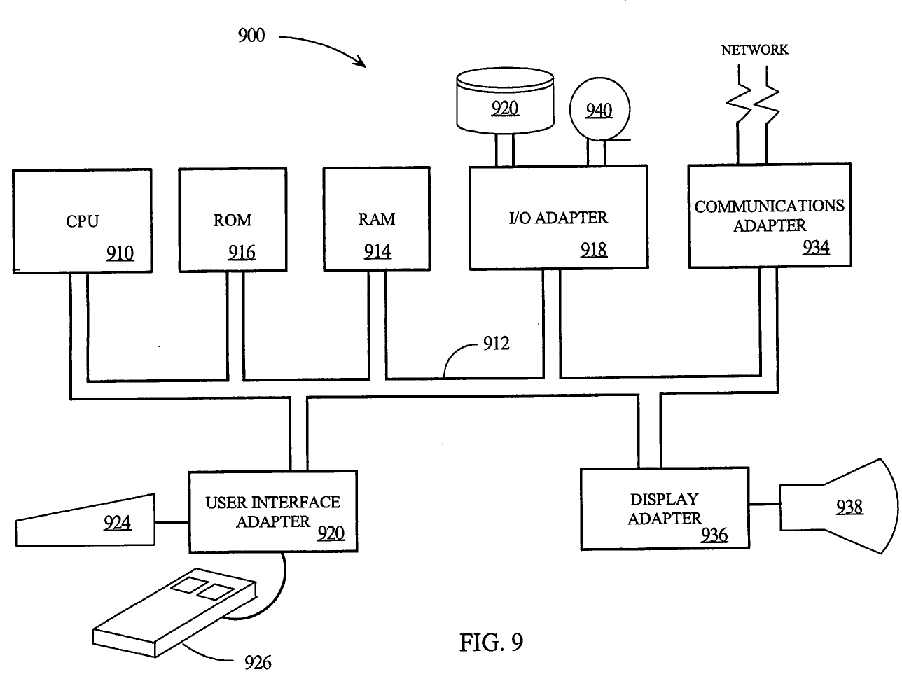

FIG. 9 is a high level functional block diagram of a representative data processing system 900 suitable for practicing the principles of the present invention. Data processing system 900 includes a central processing system (CPU) 910 operating in conjunction with a system bus 912. System bus 912 operates in accordance with a standard bus protocol, such as the ISA protocol, compatible with CPU 910. CPU 910 operates in conjunction with electronically erasable programmable read-only memory (EEPROM) 916 and random access memory (RAM) 914. Among other things, EEPROM 916 supports storage of the Basic Input Output System (BIOS) data and recovery code. RAM 914 includes, DRAM (Dynamic Random Access Memory) system memory and SRAM (Static Random Access Memory) external cache. I/O Adapter 918 allows for an interconnection between the devices on system bus 912 and external peripherals, such as mass storage devices (e.g., a hard drive, floppy drive or CD/ROM drive), or a printer 940. A peripheral device 920 is, for example, coupled to a peripheral control interface (PCI) bus, and I/O adapter 918, therefore, may be a PCI bus bridge. User interface adapter 922 couples various user input devices, such as a keyboard 924 or mouse 926 to the processing devices on bus 912. Display 938 which may be, for example, a cathode ray tube (CRT), liquid crystal display (LCD) or similar conventional display units. Display adapter 936 may include, among other things, a conventional display controller and frame buffer memory. Data processing system 900 may be selectively coupled to a computer or telecommunications network 941 through communications adapter 934. Communications adapter 934 may include, for example, a modem for connection to a telecom network and/or hardware and software for connecting to a computer network such as a local area network (LAN) or a wide area network (WAN). CPU 910 and other components of data processing system 900 may contain logic circuitry in two or more integrated circuit chips that are separated by a significant distance relative to their communication frequency such that pseudo-differential signaling employing embodiments of the present invention are used to reduce clock asymmetry and maximize the eye window of data signals according to embodiments of the present invention.

Although the present invention and its advantages have been described in detail, it should be understood that various changes, substitutions and alterations can be made herein without departing from the spirit and scope of the invention as defined by the appended claims.

What is claimed is:

1. A circuit for adjusting the duty cycle of a compensated clock signal generated from a first logic signal and a complement of the first logic signal, comprising:
a first differential amplifying means having a first input coupled to the first logic signal, a second input coupled to the complement of the first logic signal, a positive output generating a first positive output signal as a positive difference between voltage levels at the first and second inputs amplified by a programmable first gain value, and a negative output generating a first negative output signal as a negative difference between voltage levels at the first and second inputs amplified by a programmable second gain value;
a second differential amplifying means having a first input coupled to the negative output of the first differential amplifying means, a second input coupled to the positive output of the first differential amplifying means, a positive output generating a second positive output signal as a positive difference between voltage levels at the first and second inputs of the second differential amplifying means amplified by the programmable first gain value, and a negative output generating a second negative output signal as a negative difference between voltage levels at the first and second inputs of the second differential amplifying means amplified by the programmable second gain value; and
a third differential amplifying means having a first input coupled to the negative output of the second differential amplifying means, a second input coupled to the positive output of the second differential amplifying means, and an output generating the compensated clock signal as a positive difference between voltage levels of the first and second inputs of the third differential amplifying means amplified by a third gain value, wherein the programmable first and second gain values are adjusted to vary the duty cycle of the compensated clock signal.

2. The circuit of claim 1, wherein the first and second differential amplifying means each comprise:
a current source having a first node coupled to a first voltage potential of a power supply and a second node generating a bias current at a second node in response to a bias voltage;
a first field effect transistor (FET) having a source terminal coupled to the second node, a drain terminal and a gate terminal, wherein a first current is generated at the drain terminal as the amplified difference in a voltage between the gate terminal and the second node;
a first resistance network coupled between a first terminal and the drain terminal of the first FET device and generating a first variable resistance between a first terminal and the drain terminal in response to first control signals, wherein the first terminal is coupled to a second voltage potential of the power supply;
a second FET device having a source terminal coupled to the second node, a drain terminal and a gate terminal, wherein a second current is generated at the drain terminal as the amplified difference in a voltage between the gate terminal and the second node; and
a second resistance network coupled between a first terminal and the drain terminal of the second FET device and generating a second variable resistance between a first terminal and the drain terminal of the second FET device in response to second control signals, wherein the first terminal is coupled to a second voltage potential of the power supply.

3. The circuit of claim 1, wherein the third differential amplifying means comprises:
a current source having a first node coupled to a first voltage potential of a power supply and a second node generating a bias current at a second node in response to a bias voltage;
a first FET device having a source terminal coupled to the second node, a drain terminal and a gate terminal, wherein a first current is generated at the drain terminal as the amplified difference in a voltage between the gate terminal and the second node;
a first active load device having a first terminal coupled to a second voltage potential of the power supply and a second terminal coupled to the drain terminal of the first FET device and generating a first potential between the first and second terminals in response to the first current;
a second FET device having a source terminal coupled to the second node, a drain terminal and a gate terminal, wherein a second current is generated at the drain terminal as the amplified difference in a voltage between the gate terminal and the second node; and
a second active load device having a first terminal coupled to the second voltage potential of the power supply, a second terminal coupled to the drain terminal of the second FET device and a third terminal coupled to the drain terminal of the first FET device, wherein the drain terminal of the second active load device generates the compensated clock signal in response to the voltage at the drain terminal of the first FET device and the second current.

4. The circuit of claim 2, wherein the current source is an N-channel field effect transistor (FET) having a gate terminal coupled to the bias voltage, a source terminal coupled to the first voltage potential of the power supply, and a drain terminal generating the bias current.

5. The circuit of claim 2, wherein the first and second FET devices are NFETs each having the source terminal, the drain terminal and the gate terminal.

6. The circuit of claim 2, wherein the first resistance network comprises:
a first resistor having a first node coupled to the drain terminal of the first FET device and a second node coupled to a common node;
a second resistor having a first node coupled to the common node and a second node coupled to the first terminal of the first resistance network; and
a plurality of first PFETs each having a gate terminal coupled to one of the first control signals, a drain terminal coupled to the common node, and a source terminal coupled to the second voltage potential of the power supply, wherein the plurality of first PFETs are turned ON and OFF with the first control signals to modify a resistance of value of the first variable resistance of the first resistance network.

7. The circuit of claim 6, wherein the second resistance network comprises:
a first resistor having a first node coupled to the drain terminal of the first FET device and a second node coupled to a common node;
a second resistor having a first node coupled to the common node and a second node coupled to the first terminal of the second resistance network; and
a plurality of second PFETs each having a gate terminal coupled to one of the first control signals, a drain terminal coupled to the common node, and a source terminal coupled to the second voltage potential of the power supply, wherein the plurality of second PFETs are turned ON and OFF with the second control signals to modify a resistance of value of the second variable resistance of the second resistance network.

8. The circuit of claim 3, further comprising a circuit for modifying a current level of the bias current in response to a voltage level generated at the drain terminal of the first FET device.

9. The circuit of claim 8, where the circuit for modifying the current level of the bias current increases the bias current above a nominal value when the voltage at the drain terminal device increases above a nominal value.

10. The circuit of claim 1 further comprising:
a control circuit generating the programmable positive gain value and negative gain value in response to control signals; and
a circuit for generating the control signals in response to an asymmetry value of the duty cycle of the compensated clock signal.

11. An integrated circuit (IC) receiving a plurality of transmitted data signals, a clock signal, and a complement of the clock signal in alignment circuitry generating a compensated clock signal for sampling a plurality of logic data signals generated by detecting the transmitted data signals, wherein the alignment circuitry adjusts a duty cycle of the compensated clock signal in a duty cycle adjustment circuit having a first differential amplifying means having a first input coupled to the first logic signal, a second input coupled to the complement of the first logic signal, a positive output generating a first positive output signal as a positive difference between voltage levels at the first and second inputs amplified by a programmable first gain value, and a negative output generating a first negative output signal as a negative difference between voltage levels at the first and second inputs amplified by a programmable second gain value, a second differential amplifying means having a first input coupled to the negative output of the first differential amplifying means, a second input coupled to the positive output of the first differential amplifying means, a positive output generating a second positive output signal as a positive difference between voltage levels at the first and second inputs of the second differential amplifying means amplified by the programmable first gain value, and a negative output generating a second negative output signal as a negative difference between voltage levels at the first and second inputs of the second differential amplifying means amplified by the programmable second gain value, and a third differential amplifying means having a first input coupled to the negative output of the second differential amplifying means, a second input coupled to the positive output of the second differential amplifying means, and an output generating the compensated clock signal as a positive difference between voltage levels of the first and second inputs of the third differential amplifying means amplified by a third gain value, wherein the programmable first and second gain values are adjusted to vary the duty cycle of the compensated clock signal.

12. The IC of claim 11, wherein the first and second differential amplifying means each comprise:
a current source having a first node coupled to a first voltage potential of a power supply and a second node generating a bias current at a second node in response to a bias voltage;
a first FET device having a source terminal coupled to the second node, a drain terminal and a gate terminal, wherein a first current is generated at the drain terminal as the amplified difference in a voltage between the gate terminal and the second node;
a first resistance network coupled between a first terminal and the drain terminal of the first FET device and generating a first variable resistance between a first terminal and the drain terminal in response to first control signals, wherein the first terminal is coupled to a second voltage potential of the power supply;
a second FET device having a source terminal coupled to the second node, a drain terminal and a gate terminal, wherein a second current is generated at the drain terminal as the amplified difference in a voltage between the gate terminal and the second node; and
a second resistance network coupled between a first terminal and the drain terminal of the second FET device and generating a second variable resistance between a first terminal and the drain terminal of the second FET device in response to second control signals, wherein the first terminal is coupled to a second voltage potential of the power supply.

13. The IC of claim 11, wherein the third differential amplifying means comprises:
a current source having a first node coupled to a first voltage potential of a power supply and a second node generating a bias current at a second node in response to a bias voltage;
a first FET device having a source terminal coupled to the second node, a drain terminal and a gate terminal, wherein a first current is generated at the drain terminal as the amplified difference in a voltage between the gate terminal and the second node;
a first active load device having a first terminal coupled to a second voltage potential of the power supply and a second terminal coupled to the drain terminal of the first FET device and generating a first potential between the first and second terminals in response to the first current;
a second FET device having a source terminal coupled to the second node, a drain terminal and a gate terminal, wherein a second current is generated at the drain terminal as the amplified difference in a voltage between the gate terminal and the second node; and
a second active load device having a first terminal coupled to the second voltage potential of the power supply, a second terminal coupled to the drain terminal of the second FET device and a third terminal coupled to the drain terminal of the first FET device, wherein the drain terminal of the second active load device generates the compensated clock signal in response to the voltage at the drain terminal of the first FET device and the second current.

14. The IC of claim 12, wherein the current source is an N-channel field effect transistor (FET) having a gate terminal coupled to the bias voltage, a source terminal coupled to the first voltage potential of the power supply, and a drain terminal generating the bias current.

15. The IC of claim 12, wherein the first and second FET devices are NFETS each having the source terminal, the drain terminal and the gate terminal.

16. The IC of claim 12, wherein the first resistance network comprises:
a first resistor having a first node coupled to the drain terminal of the first FET device and a second node coupled to a common node;
a second resistor having a first node coupled to the common node and a second node coupled to the first terminal of the first resistance network; and
a plurality of first PFETs each having a gate terminal coupled to one of the first control signals, a drain terminal coupled to the common node, and a source terminal coupled to the second voltage potential of the power supply, wherein the plurality of first PFETs are turned ON and OFF with the first control signals to modify a resistance of value of the first variable resistance of the first resistance network.

17. The IC of claim 16, wherein the second resistance network comprises:
a first resistor having a first node coupled to the drain terminal of the first FET device and a second node coupled to a common node;
a second resistor having a first node coupled to the common node and a second node coupled to the first terminal of the second resistance network; and
a plurality of second PFETs each having a gate terminal coupled to one of the first control signals, a drain terminal coupled to the common node, and a source terminal coupled to the second voltage potential of the power supply, wherein the plurality of second PFETs are turned ON and OFF with the second control signals to modify a resistance of value of the second variable resistance of the second resistance network.

18. The IC of claim 13, further comprising a circuit for modifying a current level of the bias current in response to a voltage level generated at the drain terminal of the first FET device.

19. The IC of claim 18, where the circuit for modifying the current level of the bias current increases the bias current above a nominal value when the voltage at the drain terminal device increases above a nominal value.

20. The IC of claim 11 further comprising:
a control circuit generating the programmable positive gain value and negative gain value in response to control signals; and
a circuit for generating the control signals in response to an asymmetry value of the duty cycle of the compensated clock signal reducing an average eye window of the data signals sampled by the compensated clock signal.
